(19) United States
(12) Patent Application Publication
(10) Pub. No.: US 2020/0239687 A1
(43) Pub. Date: Jul. 30, 2020

(54) CURABLE SILICONE COMPOSITION

(71) Applicant: DOW SILICONES CORPORATION, Midland, MN (US)

(72) Inventor: Thomas Daniel Bekemeier, (US)

(21) Appl. No.: 15/762,125

(22) PCT Filed: Nov. 15, 2016
(86) PCT No.: PCT/US2016/061961

§ 371 Date: Mar. 22, 2018

(51) Int. Cl. C08L 83/04

(52) U.S. Cl. CPC C08L 83/04; C08L 2205/035; H01L 33/56; C08L 2201/10; C08L 2203/206; C08L 2205/025

(57) ABSTRACT

A curable silicone composition, the composition includes an organopolysiloxane including: an alkenyl-functional dialkylpolysiloxane with an average of at least two alkenyl groups in each molecule, a degree of polymerization between about 25 and about 10,000, at from about 20 mass % to about 50 mass % of the organopolysiloxane; an alkenyl functional organopolysiloxane resin comprising an Si0_{4/2} unit, an R¹₂R²SiO_{1/2} unit and an R¹₃SiO_{1/2} unit, wherein R¹ is C₁₋₁₀ alkyl and R² is alkenyl, the alkenyl functional organopolysiloxane resin having the alkenyl group in the range from about 1.0 mass % to about 4.5 mass %, and having an OH content of about 0.2 mass % to about 2.0 mass % and a mass averaged molecular weight of about 2,000 g/mol to about 22,000 g/mol; a crosslinking agent; and a hydrosilylation catalyst in a catalytic quantity.

The subject matter described herein relates to curable silicone compositions, the methods of forming curable silicone compositions and the cured products thereof which provide highly transparent cured silicone materials.

### BACKGROUND

In the medical, electronics and lighting industries, an optimized balance of mechanical and optical properties enable superior device function and performance. In these industries, resin reinforced silicone elastomers are widely used to achieve or enhance mechanical performance. It has been presumed and widely accepted by those skilled in the art that high mass average molecular weight alkenyl-functional organopolysiloxane resins must be included (>22,000 g/mol) to provide adequate reinforcement to these silicone elastomers.

Additionally, it has been previously demonstrated that alkenyl-functional organopolysiloxane resins provide excellent mechanical reinforcement to the silicone elastomers and, in turn, to the resulting cured material. However, as the amount of alkenyl-functional organopolysiloxane resins are increased in the composition, the optical properties are compromised due to the agglomeration and condensation of resin particles thereby resulting in the scattering of light and associated haze. This haze is detrimental in many applications where optical clarity enables device function or efficiency.

The compositions provided herein represent a significant and unexpected improvement in this balance of performance characteristics. More specifically, the present invention goes against conventional wisdom that mechanical strength and optical clarity can be balanced, maintained and improved by utilizing exclusively low mass average molecular weight (<22,000 g/mol) alkenyl-functional organopolysiloxane resins.

Furthermore, these low mass average molecular weight alkenyl-functional organopolysiloxane resins are utilizable at high concentrations in the compositions relative to the concentration of alkenyl-functional organopolysiloxane polymers in the composition thereby providing excellent surface properties which are also desirable in optical and electronics applications. Specifically, these compositions provide excellent transmission of visible light and mechanical properties while providing reduced surface-tack and favorable processing characteristics.

### SUMMARY OF THE INVENTION

The curable silicone composition of the invention includes an organopolysiloxane, a crosslinking agent and a hydrosilylation catalyst in a catalytic quantity. The organopolysiloxane has an alkenyl-functional polymer and an alkenyl-functional resin. The polymer has an average of at least two alkenyl groups in each molecule, a degree of polymerization in the range from about 25 to about 10,000, and is present in the range from about 20 mass % to about 50 mass % of the organopolysiloxane. The resin has an SiO_{4/2} unit, an R¹₂R²SiO_{1/2} unit and an R¹₃SiO_{1/2} unit in which R¹ is C₁₋₁₀ alkyl and R² is alkenyl. The resin has alkenyl in the range from about 1.0 mass % to about 4.5 mass %, a hydroxyl content on silicon in the range from about 0.2 mass % to about 2.0 mass % and a mass averaged molecular weight in the range from about 2,000 g/mol to about 22,000 g/mol.

### BRIEF DESCRIPTION OF THE DRAWINGS

FIG. 1 illustrates total optical transmittance measured for the examples discussed herein having a thickness of 0.28 centimeters (cm) as a function of wavelength using Optical Evaluation Sample Preparation C.

FIG. 2 illustrates optical haze measured for the examples discussed herein having a thickness of 0.28 cm as a function of wavelength using Optical Evaluation Sample Preparation C.

FIG. 3 illustrates optical transmittance measured for the examples discussed herein having a thickness of 1.0 cm as a function of wavelength using Optical Evaluation Sample Preparation D.

FIG. 4 illustrates total optical transmittance measured for the examples discussed herein having a thickness of 3.2 cm as a function of wavelength using Optical Evaluation Sample Preparation B.

### DETAILED DESCRIPTION

The exemplary compositions described herein are curable silicone compositions which include an organopolysiloxane (A) as the base component of the composition. The organopolysiloxane includes an alkenyl-functional organopolysiloxane polymer (A-1) and an alkenyl functional organopolysiloxane resin (A-2).

In one exemplary embodiment, (A-1) has an average of at least two alkenyl groups in each molecule. (A-1) has a polymer form with a substantially straight chain molecular structure, but a portion of the molecular chain may be somewhat branched. The alkenyl in (A-1) may include, without limitation, a vinyl, alkyl, allyl, isopropenyl, butenyl, pentenyl, hexenyl, and cyclohexenyl or a combination of any two or more thereof. The bonding position for this alkenyl may include, without limitation, the terminal position and/or a side chain position on the molecular chain. The alkyl in (A-1) may include, without limitation, a C₁₋₁₀ alkyl such as methyl, ethyl, propyl, cyclopentyl, and cyclohexyl, or a combination of any two or more thereof.

In one example embodiment, (A-1) is an alkenyl-functional dialkylpolysiloxane with an average of at least two alkenyl groups in each molecule. In another example embodiment, (A-1) is a diorganopolysiloxane and may include, without limitation, dimethylpolysiloxanes end blocked at both molecular chain terminals by dimethylvinylsiloxy groups, dimethylsiloxane-methylvinylsiloxane copolymers endblocked at both molecular chain terminals by dimethylvinylsiloxy groups, methylvinylpolysiloxanes endblocked at both molecular chain terminals by trimethylsiloxy groups, dimethylsiloxane-methylvinylsiloxane copolymers endblocked at both molecular chain terminals by trimethylsiloxy groups, or a combination of any two or more thereof.

In one example embodiment, the viscosity of (A-1) at 25° C. is from about 100 Millipascal seconds (mPa·s) to about 2,000,000 mPa·s or, more specifically, is from about 1,500 mPa·s to about 100,000 mPa·s or, even more specifically, is from about 2,000 mPa·s to about 80,000 mPa·s. When (A-1) is a mixture of two or more alkenyl-functional polyorganosiloxanes which may include high and low viscosity alkenyl-functional polyorganosiloxanes, the viscosity of this mixture at 25° C. is from about 1,000 mPa·s to about 200,000 mPa·s.

The content of (A-1) in the composition is in the range from about 20 mass % to about 50 mass % of (A) or, more specifically, in an amount from about 25 mass % to about 50 mass % of (A) or, even more specifically, in an amount from about 30 mass % to about 50 mass %. At least some reasons for this include: when the amount of (A-1) is less than the lower limit on the cited range, the flexibility of the cured silicone material provided by the cure of the composition tends to decline; when, on the other hand, the amount of (A-1) exceeds the upper limit on the cited range, the hardness of the cured silicone material provided by the cure of the present composition tends to decline. The content of (A-1) in (A) at 30 mass % to 50 mass % provides preferred processing characteristics including viscosity and flowability compared with compositions where the content of (A-1) in (A) is between 20 mass % and 30 mass %.

In one example embodiment, the vinyl-functional polydimethylsiloxane is a fluid having vinyl groups only on terminal ends and polysiloxane chain with an average degree of polymerization of about 25 to about 10,000, e.g. a formula of M^{Vi}₂D₂₅ to M^{Vi}₂D_{10,000}, where M^{Vi} is a siloxane unit including on average one vinyl group and two methyl groups, and D is a siloxane unit having two methyl groups.

In another example embodiment, the vinyl-functional polydimethylsiloxane is a fluid having vinyl groups only on terminal ends and polysiloxane chain with an average degree of polymerization of 900 with a formula of M^{Vi}₂D₉₀₀, where M^{Vi} is a siloxane unit including on average one vinyl group and two methyl groups, and D is a siloxane unit having two methyl groups.

In another example embodiment, the vinyl-functional polydimethylsiloxane is a fluid having vinyl groups only on terminal ends and polysiloxane chain with an average degree of polymerization of 500 with a formula of M^{Vi}₂D₅₀₀, where M^{Vi} is a siloxane unit having on average one vinyl group and two methyl groups, and D is a siloxane unit having two methyl groups.

In another example embodiment, the vinyl-functional polydimethylsiloxane is a fluid having vinyl groups only on terminal ends and polysiloxane chain with an average degree of polymerization of 300 with a formula of M^{Vi}₂D₃₀₀, where M^{Vi} is a siloxane unit having on average one vinyl group and two methyl groups, and D is a siloxane unit having two methyl groups.

In a further example embodiment, the vinyl-functional polydimethylsiloxane is a fluid having vinyl groups only on terminal ends and polysiloxane chain with an average degree of polymerization of 165 with a formula of M^{Vi}₂D₁₆₅, where M^{Vi} is a siloxane unit having on average one vinyl group and two methyl groups, and D is a siloxane unit having two methyl groups.

In a further embodiment, the vinyl-functional polydimethylsiloxane is a fluid having vinyl groups only on terminal ends and polysiloxane chain with an average degree of polymerization of 27 with a formula of M^{Vi}₂D₂₇, where M^{Vi} is a siloxane unit having on average one vinyl group and two methyl groups, and D is a siloxane unit having two methyl groups.

In some cases, an organopolysiloxane with a degree of polymerization of 900 or less may not provide sufficient viscosity and an organopolysiloxane with viscosity exceeding 1,000,000 mPas may be included in the composition, where without limitation, the vinyl is located at the terminal position and/or on pedant position and/or at side chain position on the molecular chain. For example, when the viscosity of (A-1) is less than 1,000 mPa·s (cP) at 25° C. the material provided by the cured composition tends to have unsatisfactory flexibility and/or low tensile strength. In this example, a suitable amount of a high viscosity organopolysiloxane may be added to the composition to provide a satisfactory flexibility and/or high tensile strength.

In one example embodiment, the high viscosity polyorganosiloxane has vinyl groups on the terminal ends only and a polysiloxane chain with an average degree of polymerization of 2000 to 15,000 with a formula of M^{Vi}₂D₂₀₀₀ to M^{Vi}₂D_{15,000}, wherein M^{Vi} is a siloxane unit having on average one vinyl group and two methyl groups, and D is a siloxane unit having two methyl groups.

In another example embodiment, the high viscosity polyorganosiloxane has vinyl groups on the terminal ends only and an average degree of polymerization of 9,463 with a formula M^{Vi}₂D_{9,463}, wherein M^{Vi} is a siloxane unit having on average one vinyl group and two methyl groups, and D is a siloxane unit having two methyl groups.

In yet another example embodiment, the high viscosity polyorganosiloxane has vinyl groups on the terminal ends and on pendent locations and polysiloxane chain with an average degree of polymerization of 9,437 including D and D^{Vi} units with a formula M^{Vi}₂D^{Vi}₁₈₇D_{9,250}, wherein M^{Vi} is a siloxane unit having on average one vinyl group and two methyl groups, D^{Vi} is a siloxane unit having on average one vinyl and one methyl group, and D is a siloxane unit having two methyl groups.

As previously mentioned, the organopolysiloxane also includes an alkenyl-functional resin (A-2). (A-2) includes the SiO_{4/2} unit (“Q” unit), R¹₂R²SiO_{1/2} unit (“M” unit with alkenyl and alkyl functionality) and R¹₃SiO_{1/2} (“M” unit with alkyl functionality) wherein R¹ is C₁₋₁₀ alkyl and R² is alkenyl. In one example embodiment, (A-2) includes a vinyl content of about 1.0 to about 4.5 weight %, an OH content due to silanol of about 0.2 to about 2.0 weight %, and a mass average molecular weight of about 2,000 to about 22,000 g/mol. More specifically, (A-2) includes a vinyl content of about 2.0 to about 4.0 weight %, an OH content on silanol of about 0.4 to about 1.8 weight %, and a mass average molecular weight of about 2,000 to about 20,000 g/mol. Even more specifically, (A-2) includes a vinyl content of about 2.8 to about 3.8 weight %, an OH content due to silanol of about 0.6 to about 1.5 weight %, and a mass average molecular weight of about 2,000 to about 15,000 g/mol.

In one example embodiment, (A-2) has a mass-average molecular weight of about 3400 g/mol wherein the vinyl group content is 3.3 mass %, the hydroxyl group content is 1.1 mass % (0.044 mole OH/mole Si), and a ratio of the total number of moles of R¹₂R²SiO_{1/2} and R¹₃SiO_{1/2} units to 1 mole of the SiO_{4/2} unit is 1.02.

In another example embodiment, (A-2) has a mass-average molecular weight of 3,380 g/mol, wherein the vinyl group content is 1.5 mass %, the hydroxyl group content is 1.1 mass % (0.045 mole OH/mole Si), and a ratio of the total number of moles of R¹₂R²SiO_{1/2} and R¹₃SiO_{1/2} units to 1 mole of the SiO_{4/2} unit is 1.00.

In a further embodiment, (A-2) has a mass-average molecular weight of 3,410 g/mol, wherein the vinyl group content is 2.3 mass %, the hydroxyl group content is 1.0 mass % (0.040 mole OH/mole Si), and a ratio of the total number of moles of R¹₂R²SiO_{1/2} and R¹₃SiO_{1/2} units to 1 mole of the SiO_{4/2} unit is 0.996.

In another example embodiment, (A-2) has a mass-average molecular weight of 3,460 g/mol wherein the vinyl group content is 3.1 mass %, the hydroxyl group content is 1.2 mass % (0.046 mole OH/mole Si), and a ratio of the total number of moles of R¹₂R²SiO_{1/2} and R¹₃SiO_{1/2} units to 1 mole of the SiO_{4/2} unit is 0.988.

In one embodiment, (A-2) has a mass-average molecular weight of 3,360 g/mol, wherein the vinyl group content is 1.6 mass %, the hydroxyl group content is 1.0 mass % (0.039 mole OH/mole Si), and a ratio of the total number of moles of R¹₂R²SiO_{1/2} and R¹₃SiO_{1/2} units to 1 mole of the SiO_{4/2} unit is 1.00.

In another example embodiment, (A-2) has a mass-average molecular weight of 3,880 g/mol, wherein the vinyl group content is 3.4 mass %, the hydroxyl group content is 0.8 mass % (0.034 mole OH/mole Si), and a ratio of the total number of moles of R¹₂R²SiO_{1/2} and R¹₃SiO_{1/2} units to 1 mole of the SiO_{4/2} unit is 1.00.

By way of comparison, in a non-inventive embodiment, the organopolysiloxane resin has a mass-average molecular weight of 23,400 g/mol, wherein the vinyl group content is 2.0 mass %, the hydroxyl group content is 1.9 mass % (0.074 mole OH/mole Si), and a ratio of the total number of moles of R¹₂R²SiO_{1/2} and R¹₃SiO_{1/2} units to 1 mole of the SiO_{4/2} unit is 0.848. When incorporated in a formulation, this organopolysiloxane resin provides adequate mechanical properties but provides poor optical transmission when the content of (A-2) exceeds 50% of (A).

In another non-inventive embodiment, the organopolysiloxane resin has a mass-average molecular weight of 26,000, wherein the vinyl group content is 4.0 mass %, the hydroxyl group content is 1.6 mass % (0.063 mole OH/mole Si), and a ratio of the total number of moles of R¹₂R²SiO_{1/2} and R¹₃SiO_{1/2} units to 1 mole of the SiO_{4/2} unit is 0.882. When incorporated in a formulation, this organopolysiloxane resin provides adequate mechanical properties but provides poor optical transmission when the content of (A-2) exceeds 50% of (A).

In one example embodiment, (A-2) is present in an amount ranging from about 50 mass % to about 80 mass % of component (A), or more preferably about 50 mass % to about 75 mass % of component (A), or most preferably about 50 mass % to about 70 mass % of component (A).

As previously stated, the curable silicone composition of the invention further includes a crosslinking agent (B) including, without limitation, an organohydrogenoligosiloxane, an organohydrogenpolysiloxane, a polyorganohydrogensiloxane, or a combination of any two or more thereof.

In one example embodiment, (B) is a combination of any two or more polyorganohydrogensiloxanes that differ in at least one of the following parameters: content of silicon hydride (SiH), molecular structure and composition (e.g. M, D, T, Q and their ratio; pendant functional groups, architecture of molecules, branch of the side chains of polymer), viscosity, average molecular weight and molecular weight distribution, number of siloxane units and the sequence with two or more types of different siloxane units.

In another example embodiment, (B) is an SiH functional organosiloxane crosslinker with an average per molecule of at least two silicon bonded hydrogen atoms and wherein (B) is selected from a single polyorganohydrogensiloxane, or a combination of two or more polyorganohydrogensiloxanes that differ in at least one of the following: a structure, a viscosity, an average molecule weight, a number of siloxane units and a sequence.

In one example embodiment, (B) is an organopolysiloxane having an average of at least three silicon-bonded hydrogen atoms in each molecule, wherein the silicon-bonded groups other than the silicon-bonded hydrogen are C₁₋₁₀ alkyl, in an amount that provides about 0.4 to about 4.0 moles silicon-bonded hydrogen in (B) per 1 mole of the total alkenyl in component (A). In this embodiment, (B) is an organopolysiloxane including: (B-1) an organopolysiloxane having at least about 0.7 mass % silicon-bonded hydrogen and comprising SiO_{4/2} units and HR³₂SiO_{1/2} units in a ratio ranging from about 1.5 to about 3.8 moles of HR³₂SiO_{1/2} units per 1 mole of SiO_{4/2} units, R R³ is C₁₋₁₀ alkyl, at about 5 mass % to about 100 mass % (about 5 mass % to about 95 mass %) of component (B); and (B-2) a straight chain organopolysiloxane having at least about 0.1 mass % silicon-bonded hydrogen, wherein the silicon-bonded groups other than the silicon-bonded hydrogen are C₁₋₁₀ alkyl, at 0 mass % to 50 mass % of component (B).

As previously stated, the curable silicone composition of the invention further includes a hydrosilylation catalyst in a catalytic quantity providing a highly transparent cured silicone material (C). In one example embodiment, (C) is added in an amount sufficient to promote curing of the composition. (C) may include a hydrosilylation catalyst known in the art and commercially available. Suitable hydrosilylation catalysts include, without limitation, a platinum group metal which includes platinum, rhodium, ruthenium, palladium, osmium, or iridium metal or an organometallic compound thereof and a combination of any two or more thereof. In further embodiments, (C) is a hydrosilylation catalyst that includes platinum black, platinum compounds such as chloroplatinic acid, chloroplatinic acid hexahydrate, a reaction product of chloroplatinic acid and a monohydric alcohol, platinum bis(ethylacetoacetate), platinum bis(acetylacetonate), platinum dichloride, and complexes of the platinum compounds with olefins or low molecular weight organopolysiloxanes or platinum compounds microencapsulated in a matrix or core-shell type structure.

In one example embodiment, (C) is a hydrosilylation catalyst solution that includes complexes of platinum with low molecular weight organopolysiloxanes that include 1,3-diethenyl-1,1,3,3-tetramethyldisiloxane complexes with platinum. These complexes may be microencapsulated in a resin matrix. In an alternative example embodiment, the catalyst includes 1,3-diethenyl-1,1,3,3-tetramethyldisiloxane complex with platinum.

Examples of suitable hydrosilylation catalysts for (C) are described in, for example, U.S. Pat. Nos. 3,159,601; 3,220,972; 3,296,291; 3,419,593; 3,516,946; 3,814,730; 3,989,668; 4,784,879; 5,036,117; and 5,175,325 and EP 0 347 895 B. Microencapsulated hydrosilylation catalysts and methods of preparing them are exemplified in U.S. Pat. Nos. 4,766,176; and 5,017,654. In another embodiment, the platinum catalyst is provided in a solution with vinyl functional organopolysiloxanes at concentrations of about 100 to about 100,000 ppm, such that when diluted in the final formulation, the total concentration is between about 0.1 and about 100 ppm.

Optionally, the curable silicone composition may further include one or more additional ingredients (D). The additional ingredient or combination of ingredients (D) may include, for example, an hydrosilylation reaction inhibitor, a mold release agent, a filler, an adhesion promoter, a heat stabilizer, a flame retardant, a reactive diluent, an oxidation inhibitor, or a combination of any two or more thereof.

In one embodiment, (D) includes an inhibitor to hydrosilylation. For example, (D) is a reaction inhibitor in order to adjust the cure rate of the curable silicone composition. In one embodiment, (D) includes, without limitation, an alkyne alcohol such as 2-methyl-3-butyn-2-ol, 3,5-dimethyl-1-hexyn-3-ol, 1-ethynyl-1-cyclohexanol, phenylbutynol or a combination of any two or more thereof; ene-yne compounds such as 3-methyl-3-pentcen-1-yne, or 3,5-dimethyl-3-hexen-1-yne, for example; as well as 1,3,5,7-tetramethyl-1,3,5,7-tetravinylcyclotetrasiloxane, 1,3,5,7-tetramethyl-1,3,5,7-tetrahexenylcyclotetrasiloxane, or benzotriazole, for example. There is no limitation on the content of this reaction inhibitor in the curable silicone composition, and this content may be selected as appropriate as a function of the molding method and curing conditions. In one embodiment, (D) is present in an amount based on a total weight of the curable silicone composition of about 10 parts per million (ppm) to about 10,000 parts per million (ppm), and more specifically from about 100 ppm to about 5,000 ppm.

In one embodiment, (D) is a reaction inhibitor to hydrosilylation is present in an amount of from about 10 to about 5,000 parts per million based on the total weight of the composition.

In one embodiment, the curable silicone composition is cured to form a highly transparent cured silicone product. The curable silicone composition can be cured to a cured silicone product having desired properties including hardness, tensile strength, elongation, optical transmission and/or any suitable combination of two or more thereof. In a further embodiment, the curable silicone composition is cured to form a cured silicone product that includes a substrate that forms a single article with a cured silicone layer.

In one embodiment, the cured silicone product has a hardness of about 5 to about 95 (Shore A), and more particular a shore hardness of about 10 to about 95 (Shore A), and more particular a hardness of about 20 to about 90 (Shore A), and even more particular a hardness of about 30 to about 90 (Shore A).

In one embodiment, the cured silicone product has a tensile strength greater than about 3 megapascals (MPa), and more particular a tensile strength greater than about 5 megapascals (MPa).

In one embodiment, the cured silicone product has an optical transmission not corrected for surface reflection losses greater than about 80% at a wavelength of 598 nanometers for 2.54 centimeters in thickness, and more particular an optical transmission greater than about 85%, and even more particular an optical transmission greater than about 90% at a wavelength of 598 nanometers for 2.54 centimeters in thickness.

In another embodiment, the curable silicone product has a total optical transmission via ASTM test method E1348-11 not corrected for surface reflection losses greater than about 80% at a wavelength of 598 nanometers for 3.2 centimeter in thickness, and more particularly greater than about 85% at a wavelength of 598 nanometers for 3.2 centimeter in thickness, and more particularly greater than about 90% at a wavelength of 598 nanometers for 3.2 centimeter in thickness.

In another embodiment, the curable silicone product has an optical attenuation coefficient as measured by the cut back method of less than about 0.01 cm⁻¹ at a wavelength of 598 nanometers.

In one embodiment, the composition has a hardness of about 60 to about 95 (Shore A), a tensile strength greater than about 3 megapascals (MPa) and a total optical transmission via ASTM test method E1348-11 not corrected for surface reflection losses greater than about 90% at 598 nanometers for 3.2 centimeters in thickness.

In one embodiment, an exemplary method of forming the composition includes mixing a solution that includes (A) an organopolysiloxane including (A-1) a vinyl-functional polyorganosiloxane and (A-2) an organopolysiloxane resin, (B) a crosslinking agent, and (C) a reaction catalyst. In another embodiment, mixing the solution includes adding (D) a reaction inhibitor.

In certain embodiments, the method further includes heating the composition to form a cured product. The heating step may further include, for example, injection molding, transfer molding, casting, extrusion, overmolding, compression molding, and cavity molding and the cured product is a molded, cast, or extruded article including lenses, lightguides, optically clear adhesive layer, or other optical elements.

In one exemplary embodiment, a curable silicone composition includes 100 mass parts of an alkenyl-containing (A) organopolysiloxane that includes (A-1) a dialkylpolysiloxane having an average of at least two alkenyl groups in each molecule and a viscosity at 25° C. of about 300 mPa·s to about 2,000,000 mPa·s, at from about 20 mass to about 50 mass % of component (A), and (A-2) an alkenyl-containing resin-form organopolysiloxane including an SiO_{4/2} unit, an R¹₂R²SiO_{1/2} unit and an R¹₃SiO_{1/2} unit, wherein R¹₂ is C₁₋₁₀ alkyl and R² is alkenyl, and the vinyl content in the alkenyl group in the range from about 1 mass % to about 4.5 mass % and the mass averaged molecular weight is between about 2,000 and about 22,000 g/mol, at from about 50 mass % to about 80 mass % of component (A), and (B) an organopolysiloxane has an average of at least two silicon-bonded hydrogen atoms in each molecule, wherein the silicon-bonded groups other than the silicon-bonded hydrogen are C₁₋₁₀ alkyl, in an amount that provides about 0.4 to about 4 moles silicon-bonded hydrogen in component (B) per 1 mole of the total alkenyl in component (A), and wherein component (B) is an organopolysiloxane that includes (B-1) an organopolysiloxane having at least about 0.7 mass % silicon-bonded hydrogen and including SiO_{4/2} units and HR³₂SiO_{1/2} units in a ratio ranging from about 1.50 to about 3.80 moles of HR³₂SiO_{1/2} units per 1 mole of SiO_{4/2} units, wherein R³ is C₁₋₁₀ alkyl, at about 5 mass % to about 95 mass % of component (B-1); and (B-2) a straight chain organopolysiloxane has at least about 0.1 mass % silicon-bonded hydrogen, wherein the silicon-bonded groups other than the silicon-bonded hydrogen are C₁₋₁₀ alkyl, at 0 mass % to about 50 mass % of component (B); and (C) a hydrosilylation reaction catalyst in a catalytic quantity, providing a highly transparent cured silicone material.

The composition exhibits excellent optical and mechanical properties appropriate for the production of clear optical and electronic devices. The combined optical clarity and mechanical toughness is derived from the preferred mass average molecular weight of the resin-form organopolysiloxane. If the mass averaged molecular weight of the resin-form organopolysiloxane (A-2) exceeds 22,000 g/mol, the optical transparency of the resulting cured composition is reduced when the content of (A-2) exceeds 50% of component (A) by mass. Similarly, if the mass averaged molecular weight of the resin-form organopolysiloxane (A-2) is less than 2000 g/mol, the mechanical toughness of the resulting cured composition is reduced when the content of (A-2) exceeds 50% of component (A) by mass. Therefore, control of the mass averaged molecular weight of the resin-form organopolysiloxane is critical to achieving optical and mechanical properties required for optical and electronic devices.

Optical device components may be produced using the composition as described herein by a method including shaping the composition and curing the composition to form a cured product, for example, for use in an optical device. Shaping the composition may be performed by injection molding, transfer molding, casting, extrusion, overmolding, compression molding, or cavity molding to produce a molded, cast, potted, dispensed, or extruded article. The method of shaping the composition will depend on various factors including a size and/or a shape of the optical device to be produced and the composition selected.

In one embodiment, the cured composition can be used in an electronic or optical device application. The electronic or optical device can be a charged coupled device, a light emitting diode, a lightguide, an optical camera, a photo-coupler, or a waveguide, for example. In another embodiment, the cured composition can be used in an optical device to facilitate evenly illuminating a surface of the optical device from which light is extracted.

In one embodiment, a highly transparent, cured silicone product is formed by curing the composition. In another embodiment, the highly transparent, cured silicone product is a molded, cast or extruded article. In yet another embodiment, the highly transparent cured silicone product includes a substrate that forms a single article with a cured silicone layer.

In another embodiment, the composition may be applied to optical parts, including, without limitation, lens, reflectors, sheets, films, bars and tubings by any fabrication method. The composition may be used for electronics, displays, soft lithography, and medical and healthcare devices. In one embodiment, the composition used as a diffuser of light or to provide a diffuse effect.

### Examples

The examples are intended to illustrate certain embodiments to one of ordinary skill in the art and should not be interpreted as limiting in the scope of the disclosure set forth in the claims.

The samples were prepared for mechanical and optical evaluation by the following methods. For each example, the method used is indicated in Table 1.

### Mechanical Evaluation Sample Preparation Y

The vinyl terminated polydimethylsiloxane, vinyl functional silicone resin, Pt catalyst, hydrogen functional cross-linker, and hydrosilylation inhibitor are added to a common vessel and mixed on a planetary mixer (Hauschild SpeedMixer DAZ 150FVZ) at 3,540 rotations per minute (rpm) for 25 seconds. The clear liquid was poured into aluminum molds and then cured at 130° C. for 3+ hours to form a solid sample, where the heat accelerates a cross-linking reaction in which the Pt catalyzes the formation of silicon—carbon bonds between hydrogen functional cross-linking molecules and vinyl functional polydimethylsiloxane and vinyl function resins. The samples had a thickness of 2.50 mm. The measurement of mechanical properties was performed on a texture analyzer (TA.HDPlus Texture Analyser, Texture Technologies Corp, NY, USA) at 23±1° C. using a dumbbell-like specimen (cut by the die of D1708, ½ scale, Fremont) in a speed of 2 mm/sec. Hardness was measured on a Shore A Durometer in accordance with ASTM D2240.

### Mechanical Evaluation Sample Preparation X

The vinyl terminated polydimethylsiloxane, vinyl functional silicone resin, Pt catalyst, hydrogen functional cross-linker, and hydrosilylation inhibitor are added to a common vessel and mixed on a planetary mixer (Hauschild SpeedMixer DAZ 150FVZ) at 3,540 rpm for 20 seconds. The clear liquid was poured into aluminum molds (1.5 mm thickness) and then pressed at 125° C. for 30 minutes into a solid sample. The solid sample was removed from the mold and post cured at 150° C. for 1 hour for mechanical property testing. The measurement of mechanical properties was performed on an Instron Mechanical Tester in accordance to ASTM D412-06A at a speed of 2 in/min. Hardness was measured on a Shore A Durometer in accordance with ASTM D2240.

### Mechanical Evaluation Sample Preparation Z

The vinyl terminated polydimethylsiloxane, vinyl functional silicone resin, Pt catalyst, hydrogen functional cross-linker, and hydrosilylation inhibitor are added to a common vessel and mixed by asymmetric centrifugal mixing on a planetary mixer (Hauschild SpeedMixer DAZ 150FVZ) at 3,540 rpm for 20 seconds. The material is then subjected to injection molding, in which a load of material is injected under pressure of 750 pounds per square inch (psi) into a metal mold cavity heated at 150° C. for 15 sec. of holding time and 30 sec. of cure time to produce an ASTM Die C specimen. Once removed from the mold cavity, the samples are subjected to an additional curing step of 150° C. for 1 hour. The measurement of mechanical properties was performed on an Instron Mechanical Tester in accordance to ASTM D412-06A at a speed of 20 in/min. Hardness was measured on a Shore A Durometer in accordance with ASTM D2240.

### Optical Evaluation Sample Preparation A

The vinyl terminated polydimethylsiloxane, vinyl functional silicone resin, Pt catalyst, hydrogen functional cross-linker, and hydrosilylation inhibitor are added to a common vessel and mixed on a planetary mixer (Hauschild SpeedMixer DAZ 150FVZ) at 3,540 rpm for 20 seconds. The liquid samples were poured into a polystyrene mold and cured at 85° C. for 3 hours followed by a post cure at 130° C. for 3 hours. The sample thickness was set to 2.54 cm. The optical properties of the samples were collected with a Perkin Elmer Lambda950 spectrophotometer. The spectrophotometer was operated at a slow scanning speed, 1 nm slit width, over a wavelength range from 200-800 nm. The reported transmittance values are not corrected for surface reflections (so called Frensel reflections) due to refractive index differences between the air and the silicone article.

### Optical Evaluation Sample Preparation B

The vinyl terminated polydimethylsiloxane, vinyl functional silicone resin, Pt catalyst, hydrogen functional cross-linker, and hydrosilylation inhibitor are added to a common vessel and mixed via asymmetric centrifugal mixing (Hauschild SpeedMixer DAZ 150FVZ) at 3,400 rpm for 60 seconds. The material is then poured into a polystyrene mold and cured for 14 hrs at 65° C. Once removed from the polystyrene mold cavity, the samples are subjected to an additional curing step of 150° C. for 1 hour. The optical properties of the molded slab samples were then collected with a Varian Cary 5000 spectrophotometer with an integrating sphere attachment. The spectrophotometer was operated at a medium scanning speed, 1 nm slit width, over a wavelength range from 200-800 nm. The Total Transmittance was determined via ASTM test method E1348-11.

### Optical Evaluation Sample Preparation C

The vinyl terminated polydimethylsiloxane, vinyl functional silicone resin, Pt catalyst, hydrogen functional cross-linker, and hydrosilylation inhibitor are added to a common vessel and mixed via asymmetric centrifugal mixing (Hauschild SpeedMixer DAZ 150FVZ) at 3,400 rpm for 60 seconds. The material is then subjected to injection molding, in which a load of material is injected under pressure of 750 psi into a metal mold cavity heated at 150° C. for 15 seconds of holding time and 30 seconds of cure time to produce a slab 0.28 cm in thickness. Once removed from the mold cavity, the samples are subjected to an additional curing step of 150° C. for 1 hour. The optical properties of the molded slab samples were collected with a Varian Cary 5000 spectrophotometer with an integrating sphere attachment. The spectrophotometer was operated at a medium scanning speed, 1 nm slit width, over a wavelength range from 200-800 nm. The Total Transmittance and haze were determined via ASTM test method E1348-11.

### Optical Evaluation Sample Preparation D

The vinyl terminated polydimethylsiloxane, vinyl functional silicone resin, Pt catalyst, hydrogen functional cross-linker, and hydrosilylation inhibitor are added to a common vessel and mixed via asymmetric centrifugal mixing (Hauschild SpeedMixer DAZ 150FVZ) at 3,400 rpm for 60 seconds. The material was then poured into a mold with cavities of length 1.0 cm, 2.5 cm, 5.0 cm, and 10.0 cm for curing at 60° C. for 14 hours. The samples are removed from the mold cavities and subjected to an additional curing step of 150° C. for 1 hour. The optical properties of the molded slab samples were then collected with a Perkin Elmer Lambda950 spectrophotometer. The spectrophotometer was operated at a slow scanning speed, 1 nm slit width, over a wavelength range from 200-800 nm. The reported transmittance values are not corrected for surface reflections (so called Frensel reflections) due to refractive index differences between the air and the silicone article.

FIG. 1 illustrates optical transmittance measured for samples of 0.28 cm thickness as a function of wavelength using the Optical Evaluation Sample Preparation C. FIG. 2 illustrates optical haze measured for samples of 0.28 cm thickness as a function of wavelength using the Optical Evaluation Sample Preparation C. FIG. 3 illustrates optical transmittance measured for samples of 1.0 cm thickness as a function of wavelength using the Optical Evaluation Sample Preparation D. FIG. 4 illustrates optical transmittance measured for samples of 3.2 cm thickness as a function of wavelength using the Optical Evaluation Sample Preparation B. Each of FIGS. 1-4 illustrate that the exemplary compositions of the present disclosure reduce or eliminate issues with transmission and haze.

### Mass Averaged Molecular Weight Evaluation

The alkenyl-functional resins were analyzed by triple detection gel permeation chromatography for molecular weight determination. The chromatographic equipment consisted of a Waters 515 pump, a Waters 717 autosampler and a Waters 2410 differential refractometer. The separation was made with two (300 mm×7.5 mm) Polymer Laboratories PLgel 5 μm Mixed-C columns (molecular weight separation range of 200 to 2,000,000), preceded by a PLgel 5 μm guard column (50 mm×7.5 mm). The analyses were performed using HPLC grade toluene flowing at 1.0 mL/min as the eluent, and the columns and detector were both controlled at 45° C. The samples were prepared in toluene at 5 mg/mL, solvated at room temperature for about three hours with occasional shaking, and filtered through 0.45 μm PTFE syringe filters prior to analysis. An injection volume of 75 μL was used and data was collected for 25 minutes. Data collection and analyses were performed using ThermoLabsystems Atlas chromatography software and Polymer Laboratories Cirrus GPC software. Molecular weight averages were determined relative to a calibration curve (3^{rd} order) created using polystyrene standards covering the molecular weight range of 580-2,300,000.

Table of Examples 1, 3, 4 and 5

| | Example 1 | Example 3 | Example 4 | Example 5 |
|---|---|---|---|---|
| Composition | | | | |
| (Parts) | | | | |
| A-1b | 50.00 | 50.00 | 50.00 | 50.00 |
| A-2a (3.3 mass % Vi) | 50.00 | 55.00 | 60.00 | 65.00 |
| B-1 | 8.93 | 9.89 | 10.75 | 11.56 |
| C-1 | 0.052 | 0.052 | 0.052 | 0.052 |
| D-1a | 0.10 | | | |
| D-1b | | 0.16 | 0.16 | 0.16 |
| [SiH]/[Vi] (mol/mol) | 1.41 | 1.49 | 1.44 | 1.45 |
| Properties | | | | |
| Sample Preparation | B | B | B | B |
| For Optical | | | | |
| Measurement and | B | B | B | B |
| Characterization | | | | |
| for Optical | | | | |
| Sample Preparation | X | X | X | X |
| For Mechanical | | | | |
| Measurement and | X | X | X | X |
| Characterization for | | | | |
| Mechanical | | | | |
| hardness (Shore A) | 80 | 81 | 85 | 87 |
| Tensile Strength at | 4.98 | 3.10 | 2.81 | 2.97 |
| break (MPa) | | | | |
| Elongation at break (%) | 53 | 24 | 17 | 20 |
| Total Optical | 94.2 | | | |
| Transmission (%) | | | | |
| 3.2 cm @ 598 nm | | | | |

Table of Examples 2a, 2b and 2c

| | Example 2a | Example 2b | Example 2c |
|---|---|---|---|
| Composition (Parts) | | | |
| A-1a | 50.00 | 50.00 | 50.00 |
| A-2a (3.3 mass % Vi) | 50.00 | 50.00 | 50.00 |
| B-1 | 8.82 | 8.82 | 8.82 |
| C-1 | 0.052 | 0.052 | 0.052 |
| D-1a | 0.10 | 0.10 | 0.10 |
| D-1b | | | |
| [SiH]/[Vi] (mol/mol) | 1.40 | 1.40 | 1.40 |
| Properties | | | |
| Sample Preparation For | B | C | D |
| Optical | | | |
| Measurement and | B | C | D |
| Characterization for | | | |
| Optical | | | |
| Sample Preparation For | X | Z | |
| Mechanical | | | |
| Measurement and | X | Z | |
| Characterization for | | | |
| Mechanical | | | |
| hardness (Shore A) | 77 | | |
| Tensile Strength at | 9.54 | | |
| break (MPa) | | | |
| Elongation at break (%) | 125 | | |
| Total Optical | | 94.0 | |
| Transmission (%) | | | |
| 0.28 cm @ 598 nm | | | |
| Optical transmission (%) | | | 93.5 |
| 1 cm @ 598 nm | | | |
| Total Optical | 93.4 | | |
| Transmission (%) | | | |
| 3.2 cm @ 598 nm | | | |

Table of Examples 8, 18, 19 and 20

| | Example 8 | Example 18 | Example 19 | Example 20 |
|---|---|---|---|---|
| Composition | | | | |
| (Parts) | | | | |
| A-1a | | 39.85 | | |
| A-1b | | | 39.85 | 29.72 |
| A-1d | 42.50 | 10.15 | 10.15 | 20.28 |
| A-1f | 7.50 | | | |
| A-2a | 50.00 | 50.00 | 50.00 | 50.00 |
| (3.3 mass % Vi) | | | | |
| B-1 | 9.89 | 9.12 | 9.23 | 9.38 |
| C-1 | 0.051 | 0.051 | 0.051 | 0.051 |
| D-1a | | 0.10 | 0.10 | 0.10 |
| D-1b | 0.15 | | | |
| [SiH]/[Vi] | 1.42 | 1.42 | 1.42 | 1.42 |
| (mol/mol) | | | | |
| Properties | | | | |
| Sample | B | B | B | B |
| Preparation | | | | |
| For Optical | | | | |
| Measurement and | B | B | B | B |
| Characterization | | | | |
| for Optical | | | | |
| Sample | X | X | X | X |
| Preparation | | | | |
| For Mechanical | | | | |
| Measurement and | X | X | X | X |
| Characterization | | | | |
| for Mechanical | | | | |
| hardness | 88 | 77 | 84 | 84 |
| (Shore A) | | | | |
| Tensile Strength | 2.01 | 6.86 | 3.75 | 2.58 |
| at break (MPa) | | | | |
| Elongation at | 16 | 75 | 71 | 32 |
| break (%) | | | | |

Table of Examples 9, 10, 13 and 14

| | Example 9 | Example 10 | Example 13 | Example 14 |
|---|---|---|---|---|
| Composition | | | | |
| (Parts) | | | | |
| A-1b | 45.00 | 45.00 | 40.00 | 40.00 |
| A-1f | 5.00 | | 10.00 | |
| A-1g | | 5.00 | | 10.00 |
| A-2a | 50.00 | 50.00 | 50.00 | 50.00 |
| (3.3 mass % Vi) | | | | |
| B-1 | 9.13 | 9.35 | 9.13 | 9.46 |
| C-1 | 0.051 | 0.051 | 0.051 | 0.051 |
| D-1b | 0.15 | 0.15 | 0.15 | 0.15 |
| [SiH]/[Vi] | 1.43 | 1.43 | 1.43 | 1.43 |
| (mol/mol) | | | | |
| Properties | | | | |
| Sample | B | B | B | B |
| Preparation | | | | |
| For Optical | | | | |
| Measurement and | B | B | B | B |
| Characterization | | | | |
| for Optical | | | | |
| Sample | X | X | X | X |
| Preparation | | | | |
| For Mechanical | | | | |
| Measurement and | X | X | X | X |
| Characterization | | | | |
| for Mechanical | | | | |
| hardness | 81 | 85 | 74 | 78 |
| (Share A) | | | | |
| Tensile Strength | 5.09 | 3.05 | 7.32 | 2.27 |
| at break (MPa) | | | | |
| Elongation at | 43 | 29 | 83 | 22 |
| break (%) | | | | |

Table of Examples 15, 16 and 17

| | Example 15 | Example 16 | Example 17 |
|---|---|---|---|
| Composition (Parts) | | | |
| A-1a | 10.15 | 20.28 | 29.69 |
| A-1b | 39.85 | 29.72 | 20.31 |
| A-2a (3.3 mass % Vi) | 50.00 | 50.00 | 50.00 |
| B-1 | 9.06 | 9.05 | 8.84 |
| C-1 | 0.051 | 0.051 | 0.051 |
| D-1a | 0.10 | 0.10 | 0.10 |
| [SiH]/[Vi] (mol/mol) | 1.43 | 1.43 | 1.40 |
| Properties | | | |
| Sample Preparation | B | B | C |
| For Optical | | | |
| Measurement and | B | B | C |
| Characterization | | | |
| for Optical | | | |
| Sample Preparation | X | X | Z |
| For Mechanical | | | |
| Measurement and | X | X | Z |
| Characterization | | | |
| for Mechanical | | | |
| hardness (Shore A) | 80 | 81 | 78 |
| Tensile Strength | 11.78 | 6.86 | 9.16 |
| at break (MPa) | | | |
| Elongation at | 113 | 73 | 124 |
| break (%) | | | |
| Total Optical | | | 94.1 |
| Transmission (%) | | | |
| 0.28 cm @ 598 nm | | | |

Table of Examples 21, 22 and 24

| | Example 21 | Example 22 | Example 24 |
|---|---|---|---|
| Composition (Parts) | | | |
| A-1a | 8.99 | 8.83 | 9.16 |
| A-1b | 26.06 | 26.14 | 26.77 |
| A-2b (1.5 mass % Vi) | 64.95 | | |
| A-2c (2.3 mass % Vi) | | 65.02 | |
| A-2d (3.1 mass % Vi) | | | 64.07 |
| B-1 | 10.06 | 10.06 | 10.06 |
| B-2 | 43.54 | 43.54 | 43.54 |
| C-1 | 0.066 | 0.066 | 0.066 |
| D-1b | 0.12 | 0.12 | 0.12 |
| [SiH]/[Vi] (mol/mol) | 3.02 | 1.94 | 1.49 |
| Properties | | | |
| Sample Preparation | A | A | A |
| For Optical | | | |
| Measurement and | A | A | A |
| Characterization | | | |
| for Optical | | | |
| Sample Preparation | Y | Y | Y |
| For Mechanical | | | |
| Measurement and | Y | Y | Y |
| Characterization | | | |
| for Mechanical | | | |
| hardness (Shore A) | 62 | 77 | 80 |
| Tensile Strength at | 1.74 | 1.73 | 1.95 |
| break (MPa) | | | |
| Elongation at break (%) | 43 | 25 | 22 |
| Optical transmission (%) | 89.0 | 91.1 | 92.1 |
| 2.54 cm @ 598 nm | | | |

Table of Examples 23, 25 and 26

| | Example 23 | Example 25 | Example 26 |
|---|---|---|---|
| Composition (Parts) | | | |
| A-1a | 8.83 | 8.86 | |
| A-1b | 26.14 | 26.17 | |
| A-1e | | | 25.07 |
| A-2c (2.3 mass % Vi) | 65.02 | | |
| A-2e (1.6 mass % Vi) | | 64.97 | |
| A-2f (3.4 mass % Vi) | | | 74.93 |
| B-1 | 10.93 | 10.93 | 12.15 |
| B-2 | | | 11.11 |
| C-1 | 0.066 | 0.066 | 0.066 |
| D-1b | 0.12 | 0.12 | 0.12 |
| [SiH]/[Vi] (mol/mol) | 1.89 | 2.76 | 1.20 |
| Properties | | | |
| Sample Preparation | A | A | A |
| For Optical | | | |
| Measurement and | A | A | A |
| Characterization | | | |
| for Optical | | | |
| Sample Preparation | Y | Y | Y |
| For Mechanical | | | |
| Measurement and | Y | Y | Y |
| Characterization | | | |
| for Mechanical | | | |
| hardness (Shore A) | 93 | 91 | 92 |
| Tensile Strength at | 3.70 | 3.21 | 3.15 |
| break (MPa) | | | |
| Elongation at break (%) | 10 | 17 | 10 |
| Optical transmission (%) | 91.1 | 86.1 | 91.5 |
| 2.54 cm @ 598 nm | | | |

Table of Comparative Examples A-C

| | Comparative | Comparative | Comparative |
|---|---|---|---|
| | Example A | Example B | Example C |
| Composition (Parts) | | | |
| A-1a | 7.36 | 15.23 | 72.28 |
| A-1b | 59.23 | 43.20 | |
| A-2g (2.0 mass % Vi) | | 41.570 | 27.72 |
| A-2h (4.0 mass % Vi) | 33.41 | | |
| B-1 | 9.52 | 4.61 | 3.07 |
| C-1 | 0.042 | 0.063 | 0.062 |
| D-1b | 0.20 | 0.20 | 0.20 |
| [SiH]/[Vi] (mol/mol) | 1.39 | 1.43 | 1.39 |
| Properties | | | |
| Sample Preparation For | D | D | D |
| Optical | | | |
| Measurement and | D | D | D |
| Characterization | | | |
| for Optical | | | |
| Sample Preparation | X | X | X |
| For Mechanical | | | |
| Measurement and | X | X | X |
| Characterization | | | |
| for Mechanical | | | |
| hardness (Shore A) | 85 | 74 | 55 |
| Tensile Strength | 6.15 | 9.10 | 5.43 |
| at break (MPa) | | | |
| Elongation at break (%) | 32 | 155 | 395 |
| Optical transmission | 92.4 | 91.8 | 92.5 |
| (%) 1 cm @ 598 nm | | | |

Table of Comparative Examples D-F

| | Comparative | Comparative | Comparative |
|---|---|---|---|
| | Example D | Example E | Example F |
| Composition (Parts) | | | |
| A-1a | | | |
| A-1b | | 67.09 | 54.70 |
| A-1c | 50.00 | | |
| A-2g (2.0 mass % Vi) | 50.00 | | 45.30 |
| A-2h ( 4.0 mass % Vi) | | 32.91 | |
| B-1 | 6.21 | 10.44 | 5.43 |
| C-1 | 0.066 | 0.066 | 0.066 |
| D-1b | 0.12 | 0.12 | 0.12 |
| [SiH]/[Vi] (mol/mol) | 1.53 | 1.92 | 1.53 |
| Properties | | | |
| Sample Preparation For | A | A | A |
| Optical | | | |
| Measurement and | A | A | A |
| Characterization for | | | |
| Optical | | | |
| Sample Preparation | Y | Y | Y |
| For Mechanical | | | |
| Measurement and | Y | Y | Y |
| Characterization for | | | |
| Mechanical | | | |
| hardness (Shore A) | 81 | 84 | 79 |
| Tensile Strength | 3.65 | 5.88 | 5.51 |
| at break (MPa) | | | |
| Elongation at break (%) | 45 | 36 | 63 |
| Optical transmission (%) | 80.3 | 82.1 | 77.7 |
| 2.54 cm @ 598 nm | | | |

### INDUSTRIAL APPLICATION

Compositions of the present disclosure may be useful for the fabrication of optical and electronic devices, such as lightguides and LED packages, for example. Products prepared by curing these compositions may provide one or more benefits including, without limitation, enhanced light transmission, enhanced reliability, and increased lifetimes of LED packages. The compositions and methods of forming the cured products may have geometries including, but not limited to, cylindrical, rectangular, simple convex lenses, patterned lenses, textured surfaces, domes, and caps. In optical device applications, the composition may be pre-manufactured by molding (injection or transfer) or casting processes. Alternatively, a process for molding over an optical device assembly, called “overmolding” or “insert molding” on a rigid or flexible substrate may also be performed using the composition described herein. The composition can be formed to a cured product having a relatively high tensile strength. The composition can be formulated to produce a cured product having a relatively high, or a relatively low hardness, depending on the desired end use of the cured product. The surface of the cured product is not sticky, and has an elastoplastic character. This combination of properties makes the composition suitable for overmolding as well as other applications. The lightguide described above may be used to transmit light from a light source to a viewing surface by internal reflection. Such applications include lighting for purposes of illumination including lamps and luminaires, backlighting units for displays, vehicle lighting, and message board applications.

The foregoing description of embodiments and examples has been presented for purposes of illustration and description. It is not intended to be exhaustive or limiting to the forms described. Numerous modifications are possible in light of the above teachings. Some of those modifications have been discussed and others will be understood by those skilled in the art. The embodiments were chosen and described for illustration of various embodiments. The scope is, of course, not limited to the examples or embodiments set forth herein, but can be employed in any number of applications and equivalent devices by those of ordinary skill in the art. Rather, it is hereby intended the scope be defined by the claims appended hereto. Additionally, the features of various implementing embodiments may be combined to form further embodiments. The word “exemplary” is used herein to mean serving as an example, instance, or illustration. Any aspect or embodiment described herein as “exemplary” is not necessarily to be construed as preferred or advantageous over other aspects or embodiments.

Reference throughout this specification to “one embodiment” or “an embodiment” may mean that a particular feature, structure, or characteristic described in connection with a particular embodiment may be included in at least one embodiment of claimed subject matter. Thus, appearances of the phrase “in one embodiment” or “an embodiment” in various places throughout this specification is not necessarily intended to refer to the same embodiment or to any one particular embodiment described. Further, it is to be understood that particular features, structures, or characteristics described may be combined in various ways in one or more embodiments. In general, of course, these and other issues may vary with the particular context of usage. Therefore, the particular context of the description or the usage of these terms may provide helpful guidance regarding inferences to be drawn for that context.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. A curable silicone composition comprising:
100 mass parts of an alkenyl-containing organopolysiloxane comprising:
a dialkylpolysiloxane having an average of at least two alkenyl groups in each molecule and a viscosity at 25° C. of about 300 mPa·s to about 2,000,000 mPa·s, at from about 20 mass % to about 50 mass % of the organopolysiloxane and
an alkenyl-containing resin-form organopolysiloxane comprising an SiO_{4/2} unit, an R¹₂R²SiO_{1/2} unit and an R¹₃SiO_{1/2} unit, wherein R¹₂ is C₁₋₁₀ alkyl and R² is alkenyl, and an alkenyl group content in the range from about 1 mass % to about 4.5 mass %, a hydroxyl content on silicon of about 0.2 mass % to about 2.0 mass %, at from about 50 mass % to about 80 mass % of the organopolysiloxane;
a crosslinking agent having an average of at least three silicon-bonded hydrogen atoms in each molecule, wherein the silicon-bonded groups other than the silicon-bonded hydrogen are C_{1_10} alkyl, in an amount that provides about 0.8 moles to about 2.0 moles silicon-bonded hydrogen per 1 mole of the total alkenyl in the organopolysiloxane, wherein the crosslinking agent itself is an organopolysiloxane comprising
an organopolysiloxane having about 0.7 mass % silicon-bonded hydrogen and comprising SiO_{4/2} units and HR³₂SiO_{1/2} units in a ratio ranging from about 1.50 to about 3.80 moles of HR³₂SiO_{1/2} units per 1 mole of SiO_{4/2} units, wherein R R³ is C₁₋₁₀ alkyl, at about 5 mass % to about 100 mass % of component (B), and
a straight chain organopolysiloxane having at least about 0.3 mass % silicon-bonded hydrogen, wherein the silicon-bonded groups other than the silicon-bonded hydrogen are C₁₋₁₀ alkyl, at 0 mass % to about 50 mass % of component (B); and
a hydrosilylation reaction catalyst in a catalytic quantity.

16. The composition of claim 15, further comprising an additional ingredient selected from the group consisting of: an inhibitor, a mold release agent, a filler, an adhesion promoter, a heat stabilizer, a flame retardant, a reactive diluent, an oxidation inhibitor, and a combination of any two or more thereof.

17. The composition of claim 16, wherein the additional ingredient comprises a reaction inhibitor to hydrosilylation, and the additional ingredient has a concentration of about 10 to about 5,000 parts per million based on the total weight of the composition.

18. The composition of claim 15, wherein the composition has a hardness of about 60 to about 95 (Shore A), a tensile strength greater than about 3 megapascals, and a total optical transmittance greater than about 90% at a wavelength of 598 nanometers for 3.2 centimeters in thickness as measured by ASTM test method E1348-11.

19. The composition of claim 15, wherein the composition has a hardness of about 60 to about 95 (Shore A), a tensile strength greater than about 3 megapascals, and an optical attenuation coefficient of less than about 0.01 cm⁻¹ measured at a wavelength of 598 nanometers.

20. A highly transparent, cured silicone product formed by curing the composition of claim 1.

21. The highly transparent, cured silicone product of claim 20 wherein the cured product is a molded, cast, or extruded article.

22. The highly transparent, cured silicone product of claim 21 comprising a substrate that forms a single article with a cured silicone layer.

23. Use of the cured product of claim 20 in an optical device application.

24. A composition according to claim 15, wherein the alkenyl-containing resin-form organopolysiloxane has a mass average molecular weight of about 2,000 to about 15,000 g/mol.
